(19) United States
(12) Patent Application Publication
(10) Pub. No.: US 2014/0342102 A1
(43) Pub. Date: Nov. 20, 2014

(54) Small Feature Size Fabrication Using a Shadow Mask Deposition Process

(71) Applicant: ADVANTECH GLOBAL, LTD, Tortola (VG)

(72) Inventors: Thomas F. Ambrose, Sewickley, PA (US); Byron B. Brocato, Pittsburgh, PA (US); Jong Guang Pan, Shanghai (CN)

(73) Assignee: ADVANTECH GLOBAL, LTD, Tortola (VG)

(21) Appl. No.: 14/282,021

(22) Filed: May 20, 2014

Related U.S. Application Data
(60) Provisional application No. 61/825,188, filed on May 20, 2013.

(51) Int. Cl. C23C 16/04; C23C 14/34; C23C 16/503; C23C 14/46

(52) U.S. Cl. CPC C23C 16/042; C23C 14/46; C23C 14/3442; C23C 16/503
USPC 427/569; 204/298.11; 204/298.04; 204/192.12; 204/192.11; 118/721

(57) ABSTRACT

In a system and method of depositing material on a substrate, a shadow mask, including one or more apertures therethrough, in intimate contact with the substrate is provided inside of a chamber or reactor. Material ejected from a solid target material is deposited on one or more portions of the substrate after passage through the one or more apertures of the shadow mask. Desirably, a target-to-substrate distance is within a mean free path length at a specified deposition pressure. Alternatively, an electric field acts on a process gas to create a plasma that includes ionized atoms or molecules of the material that are deposited on one or more portions of the substrate after passage through the one or more apertures of the shadow mask.

### CROSS REFERENCE TO RELATED APPLICATION

The present application claims priority to U.S. Provisional Application No. 61/825,188, filed May 20, 2013, entitled “Small Feature Size Fabrication Using a Shadow Mask and Sputter Deposition Process”, the entire disclosure of which is hereby incorporated by reference in its entirety.

### BACKGROUND OF THE INVENTION

1. Field of the Invention

The present invention relates to a system and method for depositing material on a substrate and, more particularly, to sputter deposition, ion beam deposition, and/or PECVD deposition of material on portions or sections of the substrate via apertures in a shadow mask that is in intimate contact with the substrate.

2. Description of Related Art

Heretofore, thermal or electron beam evaporation of materials (metals, insulators and semiconductors) through a shadow mask was used to produce fine features, on the order of micron size, to fabricate circuits and/or fine lines for interconnects. An advantage of using evaporation through a shadow mask is the “line of sight” deposition produces small features with crisp edges and almost perfect vertical side walls. Evaporation, while useful, has certain limitations, such as, without limitation, being able to reach the melting temperature or vapor pressure of refractory metals, such as molybdenum. Therefore only certain materials can be evaporated. Furthermore controlling the growth rate and the repeatability of film quality from sample to sample is difficult and requires operator intervention to monitor the deposition process. Thus for a production environment, using evaporation for thin film deposition is not preferred.

### SUMMARY OF THE INVENTION

Small size features for microcircuit and/or fine line interconnects can be fabricated using a sputter deposition process under appropriate sputter deposition process conditions and a shadow mask that includes micron size apertures. Low sputter pressure along with a short sputter target-to-substrate distance achieves crisp edge features and minimizes the amount of feature overspray while providing smooth sidewalls. Low sputter pressure reduces the number of collisions of sputtered atoms to mimic “line of sight” deposition. Desirably, the target-to-substrate distance is within the mean free path length at a specific sputtering pressure.

More specifically, disclosed herein is a system for depositing material on a substrate. The system comprises: a vacuum chamber or reactor; a target material positioned in the vacuum chamber or reactor; a substrate positioned in the vacuum chamber or reactor in spaced relation to the target material for receiving a deposit of atoms or molecules that have been ejected from the target material; and a shadow mask, including one or more apertures therethrough, in intimate contact with the substrate between the target material and the substrate, wherein during deposition of atoms or molecules ejected from the target material onto the substrate via the one or more apertures in the shadow mask, a distance D between surfaces of the substrate and the target material that face the shadow mask is ≦a mean free path (λ) of the atoms or molecules of material that has been ejected from the target material.

The mean free path (λ) of the atoms or molecules of material is: λ(cm)=5×10⁻³/P (Torr), where P is the vacuum pressure in the vacuum chamber or reactor.

The system can include means for ejecting the atoms or molecules from the target material.

The means for ejecting the atoms or molecules from the target material can include: an anode and a cathode positioned by the respective substrate and the target material; and a DC or AC power supply connected to apply a positive voltage to the anode and/or a negative voltage to the cathode.

Alternatively, the means for ejecting the atoms or molecules from the target material can include an ion beam source positioned for directing to the target material an ion beam that causes the atoms or molecules to be ejected from the target material.

The distance D can be ≦10 cm; or ≦7 cm; or ≦5 cm.

Also disclosed is a method of depositing material on a substrate comprising: (a) providing inside of a chamber or reactor a shadow mask, including one or more apertures therethrough, in intimate contact with a substrate; (b) providing inside of the chamber or reactor a target material in spaced relation to a side of the shadow mask opposite the substrate; (c) following steps (b) and (c), causing the chamber or reactor to be evacuated to a pressure below 5×10⁻³ Torr; (d) following step (c), causing atoms or molecules to be ejected from the target material onto the substrate via the one or more apertures in the shadow mask, wherein, during step (d), a distance D between surfaces of the substrate and the target material that face the shadow mask is ≦a mean free path (A) of the atoms or molecules of material that has been ejected from the target material.

The atoms or molecules can be ejected from the target material via sputtering.

The atoms or molecules can be ejected from the target material via an ion beam.

Also disclosed is a method of depositing material on a substrate comprising: (a) providing inside of a reactor a shadow mask, that includes one or more apertures therethrough, in intimate contact with a substrate; (b) following step (a), introducing into the reactor a process gas that includes an element desired to be deposited on the substrate; and (c) following step (b), via an electric field acting on the process gas, creating a plasma that includes ionized atoms or molecules of the element that are deposited on one or more portions of the substrate after passage through the one or more apertures of the shadow mask.

The electric field can be a DC or AC electric field.

Step (b) can further include introducing into the reactor an inert gas.

The method can further include between steps (a) and (b) evacuating the reactor.

Also disclosed is a method of depositing material on a substrate comprising: (a)providing inside of a chamber or reactor a shadow mask, including one or more apertures therethrough, in intimate contact with a substrate; (b) providing inside of the chamber or reactor a material to a side of the shadow mask opposite the substrate; (c) evacuating the chamber or reactor; and (d) causing atoms or molecules from the material to be deposited on a surface of the substrate via the one or more apertures in the shadow mask, wherein, during step (d), a distance D between the material and the surface of the substrate is ≦a mean free path (A) the atoms or molecules of material travel in the chamber or reactor.

The material can be a gas or a solid. Step (d) can include depositing the atoms or molecules via one of the following processes: sputtering, ion beam deposition, or chemical vapor deposition.

### BRIEF DESCRIPTION OF THE DRAWINGS

FIG. 1 is a schematic representation of a sputtering system including a shadow mask in intimate contact with a deposition substrate;

FIGS. 2A-2E are examples of optical micrographs of 80 micrometer square features sputtered at different background gas pressures, where the target-to-substrate distance was fixed at 7 cm;

FIG. 3 is a cross-section of a sputtered side wall varying from substantially vertical to a sloped value in response to changing background gas pressure;

FIG. 4 is a schematic representation of an ion beam deposition system including a shadow mask in intimate contact with a deposition substrate; and

FIG. 5 is a schematic representation of a PECVD deposition system including a shadow mask in intimate contact with a deposition substrate.

### DESCRIPTION OF THE INVENTION

The present invention will be described with reference to the accompanying figures where like reference numbers generally correspond to like elements.

Sputter deposition is a thin film deposition technique where atoms of specific target material are ejected from a target by ionized gas particles (sputtering) in a well-controlled process. Various forms of sputtering processes exist using either a magnetron cathode, diode cathode, or ion beam to deposit a thin film on a substrate. Any thin film can be deposited from a solid target using a sputtering process which also permits deposition either up or down (note, evaporation can be only deposition up). The only requirement for the sputtering deposition process is a background gas (typically an inert gas such as argon or xenon), which is required for the sputtering process. This background gas increases the vacuum pressure (usually in the 3-5 mTorr range) and limits the average distance an atom ejected from the target, i.e., a sputtered atom, can travel without colliding with another sputtered atom. This distance, known as the mean free path (λ), is inversely proportional to the vacuum pressure and can be expressed by the following equation:

λ(cm)=5×10⁻³/P (Torr)

where P is the vacuum pressure.

TABLE 1
Calculated mean free path as a function of vacuum pressure.

| Background Gas Pressure (Torr) | Mean Free Path [λ] |
|---|---|
| 1 atm. (760 Torr) | 6 μm |
| 5 × 10⁻³ | 1 cm |
| 1 × 10⁻³ | 5 cm |
| 5 × 10⁻⁶ (typical evaporation pressure) | 1000 cm |

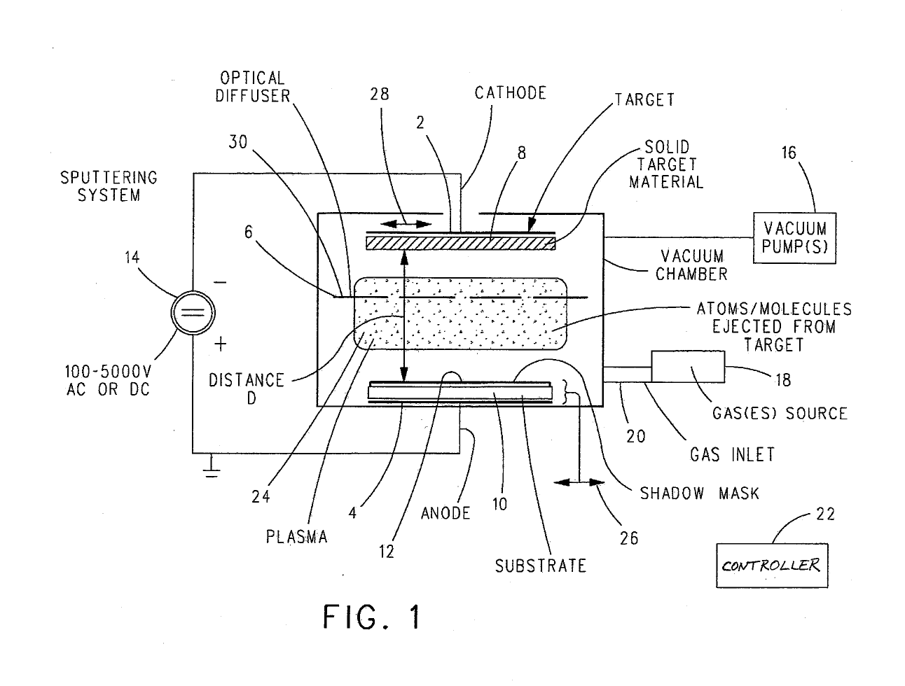

Thus, as can be seen in Table 1, for a typical sputter deposition process with a background pressure of 5 mTorr the mean free path is on the order of 1 cm. Hence if the target to substrate distance is greater than 1 cm, the probability that the sputtered atom will collide with another sputtered atom before reaching the substrate is high. FIG. 1 is a schematic view of an exemplary sputtering system.

The exemplary sputtering system of FIG. 1 includes a cathode 2 and an anode 4 inside of a vacuum chamber 6. A target 8 comprised of solid target material and a deposition substrate 10 to receive a deposit of target material ejected from target 8 are positioned in spaced relation to each other between and adjacent cathode 2 and anode 4, respectively. A shadow mask 12 is positioned in intimate contact with substrate 10 between target 8 and substrate 10. A power supply 14 has its negative or ground terminal connected to cathode 2 and its positive terminal connected to anode 4.

One or more vacuum pump(s) 16 are connected to vacuum chamber 6 and are operative for reducing the pressure within vacuum chamber 6 to a desirable vacuum pressure for sputtering target material from target 8 onto substrate 10 via one or more apertures (not shown) in shadow mask 12.

A process gas(es) source 18 is coupled to vacuum chamber 6 via a gas inlet 20.

An optional controller 22 may be provided for controlling and coordinating the operation of power supply 14 (which may be an AC or DC voltage source), vacuum pump(s) 16, and the flow of process gas into vacuum chamber from gas(es) source 18. Gas(es) source 18 can be the source of background gas such as, without limitation, argon or xenon.

In operation, vacuum pump(s) 16 and the flow of background gas from gas(es) source 18 into vacuum chamber 6 is controlled in a manner to establish a desired background gas pressure within vacuum chamber 6. At a suitable time, power supply 14 is enabled whereupon the background gas present in vacuum chamber 6 between cathode 2 and anode 4 is ionized thereby producing a plasma 24 between target 8 and shadow mask 12 in intimate contact with substrate 10. In a manner known in the art, ionized atoms in plasma 24 are accelerated by cathode 2 into contact with target 8. In response to interaction between these accelerated ions and the target material of target 8, atoms or molecules of target material are ejected from target 8 toward the side of shadow mask 12 facing target 8 and the portions of substrate 10 that face target 8 through the one or more apertures in shadow mask 12.

After passage across a distance D between the opposing surfaces of target 8 and substrate 10 and the one or more apertures in shadow mask 12, the atoms or molecules of target material ejected from target 8 forcibly contact and embed in substrate 10. After a period of time, the cumulative effect of atoms or molecules of target material ejected from target 8 embedding into substrate 10 results in the formation of a film of target material on the portions of substrate 10 exposed to said atoms or molecules of target material via apertures in substrate 12. Similarly, atoms or molecules of target material ejected from target 8 that impinge on the surface of shadow mask 12 facing target 8 form a film of target material on said surface of shadow mask 12.

To use a sputter deposition process in conjunction with shadow mask 12 in intimate contact with substrate 10 to produce small features with crisp edges, certain process conditions must be met. Namely, the background gas pressure must be low (desirably <1 mTorr) and the target 8 to substrate 10 distance D is desirably below 10 cm.

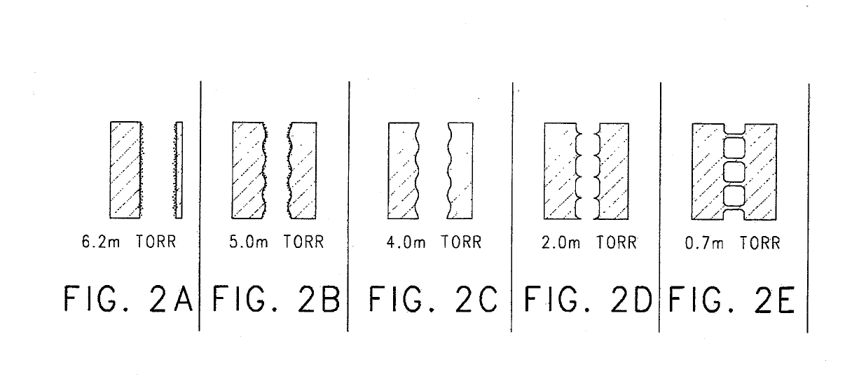

As an example, FIGS. 2A-2E show optical micrographs of 80 μm square features as a function of background gas pressure. In this example, the target 8 to substrate 10 distance D, i.e., the distance between opposing faces of target 8 and substrate 10, was fixed at 7 cm. As shown, the feature edges become more crisp and sharp (more defined) when the background gas pressure is decreased, e.g., ≦1 mTorr.

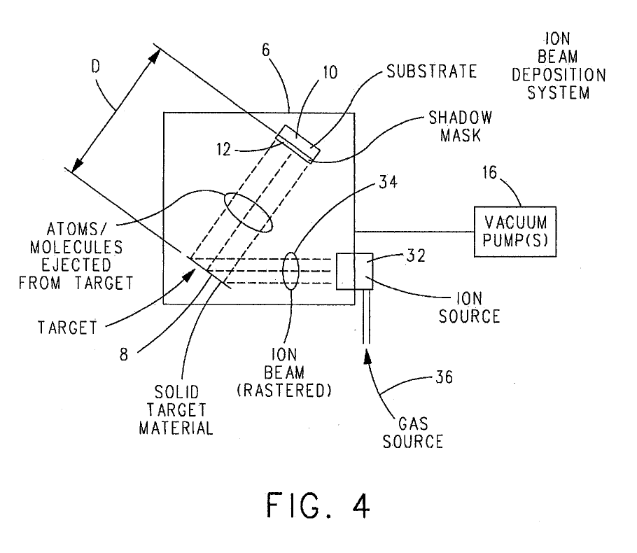

Using sputter deposition in combination with shadow mask 12 in intimate contact with substrate 10 enables fabrication of patterns on substrate 10 with small size features having crisp, sharp and well-defined edges for use in micro-circuitry fabrication and fine line interconnects on substrate 10. The sputter deposition process can be magnetron sputtering (both dc and rf), diode sputtering (FIG. 1), and/or ion beam deposition sputtering (FIG. 4). The sputter deposition process enables a larger variety of target materials to be used as compared to evaporation deposition. The sputtering process enables both sputter down and sputter up film deposition.

Sputter power values may range from tens of watts to thousands of watts but these values are chosen to maximize growth rates without generating excessive heat on substrate 10. The background gas in vacuum chamber 6 may include gases such as argon or xenon, either alone or with the addition of reactive gases such as oxygen and nitrogen for oxide and nitride formation. For example, an exemplary ratio of argon/oxygen or argon/nitrogen can be ˜95/5-90/10 range. For optimum sputtering results, the overall background gas pressure in the sputtering environment is desirably below 3 mTorr.

As is known in the art, sputter deposition growth rate of sputtered material onto substrate 10 varies linearly with sputter power. Using a heavier inert gas, (specifically a heavier atomic mass) such as xenon compared to argon, also increases the deposition rate due to kinematics. Increasing sputter power will increase the temperature of substrate 10 (and shadow mask 12), with the increase in temperature proportional to the increase in sputter power.

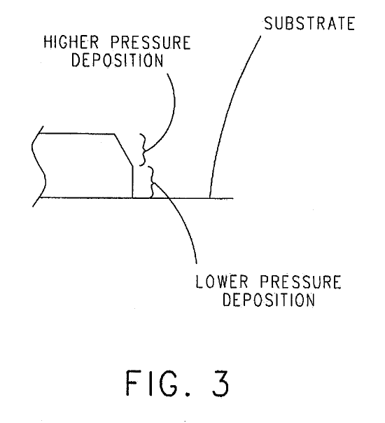

The background gas pressure in vacuum chamber 6 during sputter deposition is desirably low (e.g., between 0.2 mTorr-2.5 mTorr) to ensure crisp, sharp and well-defined features by allowing for a large mean free path and line of sight deposition. By changing the background gas pressure, the feature side wall profile may be adjusted for a particular application. For example, a sloped sidewall may be advantageous to device fabrication allowing for a gradual change in feature profile without sharp edges that may cause voltage breakdown across an insulating layer. As shown in FIG. 3, the slope of a sidewall may be varied in a single sidewall from substantially vertical (90 degrees) to a sloped value e.g., (60 degrees) by changing the background gas pressure from a lower gas pressure to a higher gas pressure, respectively, during sputter deposition of said sidewall.

The target 8 to substrate 10 distance D is desirably on the order of the mean free path length or less to ensure line of sight deposition. The distance D may be as large as 250 mm, however “shorter distances” (≦10 cm) are envisioned which are desirably chosen to minimize heating of shadow mask 12 and substrate 10 caused by sputtered molecules or atoms impinging thereon. The “shorter distances” (≦10 cm) between target 8 and substrate 10 are based on mean free path (discussed above). The distance D between target 8 and substrate 10 is desirably on the order of 1 mean free path length or less to avoid excessive scattering of sputtered molecules or atoms. The above Table 1 of calculated mean free path as a function of background gas pressure is a first order approximation of a desired target 8 to substrate 10 distance D. It is envisioned that optimal target 8 to substrate 10 distance D may be adjusted for a specific sputtering chamber geometry. In general, thermal management of shadow mask 12 is desirably controlled to keep the features being sputtered on substrate 10 the correct size and in the correct position.

An optional diffuser (or beam collimator) 30 may also be used during sputter deposition by placing diffuser 30 between target 8 and the combination of shadow mask 12 in contact with substrate 10 (i.e., the shadow mask/substrate sandwich). Diffuser 30 assists in reducing substrate heat by absorbing secondary electrons generated during the sputtering process, thereby reducing the number of sputtered atoms or molecules impinging on substrate 10, as well as providing additional collimation of the sputtered atoms or molecules by blocking randomly scattered sputtered atoms or molecules.

Lastly, to reduce the generation of heat on substrate 10 caused by sputtered atoms or molecules impinging on substrate 10, the combination of shadow mask 12 in intimate contact with substrate 10 (i.e., the shadow mask/substrate sandwich) may be scanned across or rotated above or below the sputter target 8, cathode 2 combination (as shown by two-headed arrow 26 in FIG. 1). Also or alternatively, the sputter target 8, cathode 2 combination can be scanned across the combination of shadow mask 12 in intimate contact with substrate 10 (as shown by two-headed arrow 28 in FIG. 1) to reduce heat caused by sputtered atoms or molecules striking substrate 10. Both actions not only improve film thickness uniformity while reducing heat caused by sputtered atoms or molecules impinging on substrate 10 but also eliminate sputter dark spots or regions where non-uniformities in film thickness result on substrate 10.

The use of Ion Beam Deposition (IBD) described above or Plasma-Enhanced Chemical Vapor Deposition (PECVD) in replacement of sputter deposition of material from target 8 onto substrate 10 via openings or windows in shadow mask 12 described above is envisioned.

With reference to FIG. 4, an ion beam deposition system includes vacuum chamber 6, target 8, substrate 10 with shadow mask 12 in intimate contact therewith, and vacuum pump(s) 16 for creating within vacuum chamber 6 a suitable background pressure for conducting ion beam deposition within vacuum chamber 6. Ion beam deposition system also includes an ion source 32 positioned to project (or raster) an ion beam 34 onto target 8. In response to the ions of ion beam 34 impacting target 8, atoms or molecules of target material are ejected from target 8. After traveling distance D, these ejected atoms or molecules impact and become embedded in the portions of substrate 10 exposed to target 8 via the openings or windows in shadow mask 12 after passage of these atoms or molecules via said openings or windows. The ions of ion beam 34 may be produced in any suitable and/or desirable manner by ion source 32, e.g., by ionization of atoms and/or molecules of a suitable gas from a gas source 36.

After a sufficient time of exposure to the atoms or molecules ejected from target 8, a film of material forms on those portions of substrate 10 aligned with the openings or windows in shadow mask 12. Obviously, a film of target material also forms on the surface of shadow mask 12 facing target 8.

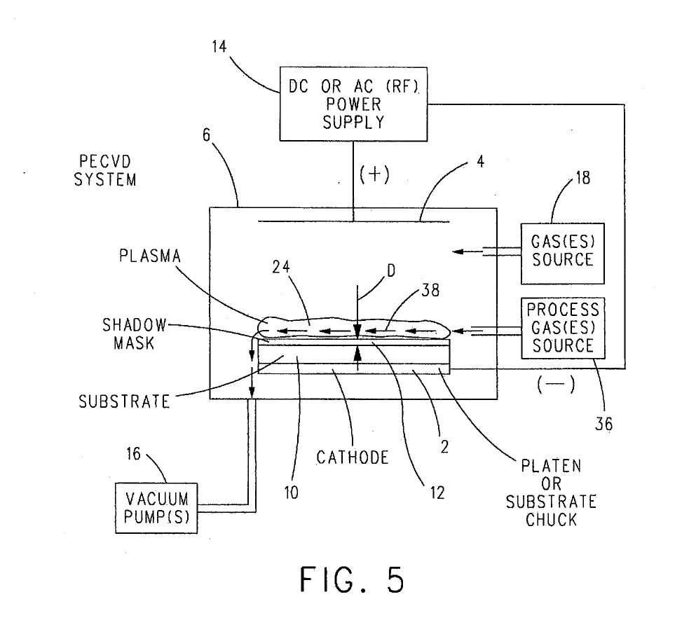

With reference to FIG. 5, a plasma enhanced chemical vapor deposition (PECVD) system includes a cathode 2 and an anode 4 in spaced relation within a vacuum chamber 6, with anode 4 connected to a positive terminal of power supply 14 and with cathode 2 connected to a negative terminal of power supply 14.

Connected to vacuum chamber 6 are one or more vacuum pump(s) 16, gas(es) source 18 (e.g., argon or xenon), and a process gas(es) source 36. Positioned adjacent cathode 2 is substrate 10 with shadow mask 12 in intimate contact with a surface of substrate 10 that faces anode 4. As discussed above, one or more portions of substrate 10 are exposed through openings or windows in shadow mask 12.

In operation, vacuum pump(s) 16, gas(es) source 18, and process gas(es) source 36 are controlled to produce a suitable deposition environment within vacuum chamber 6, with gas from process gas(es) source 36 flowing across the surface of shadow mask 12 facing anode 4. In this case, gas 38 from process gas(es) source 36 includes a suitable molecule or compound desired to be deposited on the portions of substrate 10 in alignment with the windows or openings in shadow mask 12. For example, silicon dioxide can be deposited using a combination of silicon precursor gases, like dichlorosilane or silane and oxygen precursors, such as oxygen and nitrous oxide, typically at background gas pressures from a few millitorr to a few torr. Plasma-deposited silicon nitride, formed from silane and ammonia or nitrogen, is also widely used. Plasma nitrides, which contain a large amount of hydrogen, can be bonded to silicon (Si—H) or nitrogen (Si—NH). Silicon dioxide can also be deposited from a tetraethoxysilane silicon precursor in an oxygen or oxygen-argon plasma.

At a suitable time after a flow of gas 38 has been established across the surface of shadow mask 12, power supply 14 is engaged forming an electric field that ionizes gas 38 forming a plasma 24. Ions from plasma 24 are accelerated by the potential of cathode 2 into contact with the portions of substrate 10 aligned with the windows or openings in shadow mask 12 where said ions embed into substrate 10 over time forming a film on the portions of substrate 10 aligned with the windows or openings in shadow mask 12. After a suitably thick layer of material has been deposited on the portions of substrate 10 aligned with the windows or openings in shadow mask 12, the operation of power supply 14 is terminated and the flow of gas 38 from process gases source 36 is terminated.

As can be understood from the PECVD system shown in FIG. 5, the distance D can be on the order of tens or hundreds of millimeters up to one centimeter. Accordingly, it is possible to use higher background gas pressures for deposition utilizing the PECVD system of FIG. 5 versus the sputtering system of FIG. 1 or the ion beam deposition system of FIG. 4. However, this is not to be construed as limiting the invention.

The present invention has been described with reference to exemplary embodiments. Obvious combinations and alterations will occur to others upon reading and understanding the preceding detailed description. For example, while the use of a sputtering system, an ion beam deposition system, and a PECVD system have been disclosed, it is envisioned that the present invention can also be realized with other types of vacuum deposition systems. Accordingly, it is intended that the invention be construed as including all such modifications and alterations insofar as they come within the scope of the appended claims or the equivalents thereof.

1. A system for depositing material on a substrate, said system comprising:
a vacuum chamber or reactor;
a solid target material positioned in the vacuum chamber or reactor;
a substrate positioned in the vacuum chamber or reactor in spaced relation to the target material for receiving a deposit of atoms or molecules that have been ejected from the target material; and
a shadow mask, including one or more apertures therethrough, in intimate contact with the substrate between the target material and the substrate, wherein during deposition of atoms or molecules ejected from the target material onto the substrate via the one or more apertures in the shadow mask, a distance D between surfaces of the substrate and the target material that face the shadow mask is ≦a mean free path (λ) of the atoms or molecules of material that have been ejected from the target material.

2. The system of claim 1, wherein the mean free path (λ) of the atoms or molecules of material is:
λ(cm)=5×10−3/P (Torr)
where P is the vacuum pressure in the vacuum chamber or reactor.

3. The system of claim 1, further including means for ejecting the atoms or molecules from the target material.

4. The system of claim 3, wherein the means for ejecting the atoms or molecules from the target material includes:
an anode and a cathode positioned by the respective substrate and the target material; and
a power supply connected to apply an electrical potential to at least one of the anode and the cathode.

5. The system of claim 1, wherein the means for ejecting the atoms from the target material includes an ion beam source positioned for directing to the target material an ion beam that causes the atoms to be ejected from the target material.

6. The system of claim 1, wherein the distance D≦10 cm.

7. The system of claim 1, wherein the distance D≦7 cm.

8. The system of claim 1, wherein the distance D≦5 cm.

9. A method of depositing material on a substrate, said method comprising:
(a) providing inside of a chamber or reactor a shadow mask, including one or more apertures therethrough, in intimate contact with a substrate;
(b) providing inside of the chamber or reactor a solid target material in spaced relation to a side of the shadow mask opposite the substrate;
(c) following steps (b) and (c), causing the chamber or reactor to be evacuated to a pressure below 5×10−3 Torr;
(d) following step (c), causing atoms or molecules to be ejected from the target material onto the substrate via the one or more apertures in the shadow mask, wherein, during step (d), a distance D between surfaces of the substrate and the target material that face the shadow mask is ≦a mean free path (λ) of the atoms or molecules of material that has been ejected from the target material.

10. The method of claim 9, wherein the atoms or molecules are ejected from the target material via sputtering.

11. The method of claim 9, wherein the atoms or molecules are ejected from the target material via an ion beam.

12. The system of claim 9, wherein the distance D≦10 cm.

13. The system of claim 9, wherein the distance D≦7 cm.

14. The system of claim 9, wherein the distance D≦5 cm.

15. A method of depositing material on a substrate, said method comprising:
(a) providing inside of a chamber or reactor a shadow mask, that includes one or more apertures therethrough, in intimate contact with a substrate;
(b) following step (a), introducing into the chamber or reactor a process gas that includes an element desired to be deposited on the substrate; and
(c) following step (b), via an electric field acting on the process gas, creating a plasma that includes ionized atoms or molecules of the element that are deposited on one or more portions of the substrate after passage through the one or more apertures of the shadow mask.

16. The method of claim 15, wherein the electric field is a DC or AC electric field.

17. The method of claim 15, wherein step (b) further includes introducing an inert gas into the chamber or reactor.

18. The method of claim 15, further including between steps (a) and (b) evacuating the chamber or reactor.

19. A method of depositing material on a substrate, said method comprising:
(a) providing inside of a chamber or reactor a shadow mask, including one or more apertures therethrough, in intimate contact with a substrate;
(b) providing inside of the chamber or reactor a material to a side of the shadow mask opposite the substrate;
(c) evacuating the chamber or reactor;
(d) causing atoms or molecules from the material to be deposited on a surface of the substrate via the one or more apertures in the shadow mask, wherein, during step (d), a distance D between the material and the surface of the substrate is ≦a mean free path (λ) the atoms or molecules of material travel in the chamber or reactor.

20. The method of claim 9, wherein:
the material is a gas or a solid; and
step (d) includes depositing the atoms or molecules via one of the following processes:
sputtering, ion beam deposition, or chemical vapor deposition.
